(19) United States
(12) Patent Application Publication
(10) Pub. No.: US 2025/0055420 A1
(43) Pub. Date: Feb. 13, 2025

(54) POWER AMPLIFIER SYSTEM WITH GAIN EXPANSION COMPENSATION

(71) Applicant: Qorvo US, Inc., Greensboro, NC (US)

(72) Inventors: Baker Scott, San Jose, CA (US); George Maxim, Saratoga, CA (US); Chong Woo, Fremont, CA (US)

(21) Appl. No.: 18/706,432

(22) PCT Filed: Nov. 22, 2022
(86) PCT No.: PCT/US2022/050658

§ 371 Date: May 1, 2024

Related U.S. Application Data
(60) Provisional application No. 63/282,952, filed on Nov. 24, 2021.

(51) Int. Cl. H03F 1/22; H03F 1/02; H03F 1/56; H03F 3/193; H03F 3/21; H03F 3/24; H03F 3/26; H03G 3/30

(52) U.S. Cl. CPC H03F 1/223; H03F 1/0266; H03F 1/0272; H03F 1/56; H03F 3/193; H03F 3/211; H03F 3/245; H03F 3/265; H03G 3/3042; H03F 2200/451; H03F 2203/30084; H03F 2203/30117; H03G 2201/103; H03G 2201/206

(57) ABSTRACT

Disclosed is a power amplifier having an output stage (12) having a radio frequency (RF) output (14) and an RF input (16) and a driver stage (18) having a driver input (20) coupled to the RF input (16), a control input (22), and a driver output (24), wherein the driver stage (18) is configured to have a controllable soft compression characteristic that substantially neutralizes a gain expansion characteristic of the output stage (12). Also included is a controller (26) having a control output (28) coupled to the control input (22) of the driver stage (18), wherein the controller (26) is configured to generate a control signal at the control output (28) that controls the soft compression characteristic of the driver stage (18).

### RELATED APPLICATIONS

This application claims the benefit of provisional patent application Ser. No. 63/282,952, filed Nov. 24, 2021, the disclosure of which is hereby incorporated herein by reference in its entirety.

### FIELD OF THE DISCLOSURE

The present disclosure relates to a radio frequency power amplifier that compensates for gain expansion of the output stage of the radio frequency power amplifier.

### BACKGROUND

A traditional power amplifier uses one or more driver stages that operate relatively linearly up to the point that the driver stages reach compression. In other cases, the gain curve of the driver stage may be affected by the rectification of the bias point, but the driver stage does not have an external control terminal to receive a control signal. In many 5G power amplifiers where it is desired to reduce the quiescent power consumption, an output stage of the power amplifier is debiased strongly. This debiasing leads to significant gain expansion as the signal grows. The position at which the expansion happens depends on the power amplifier operation conditions and thus can have some variability. If nothing is done to compensate such expansion, the overall power amplifier gain characteristic presents the expansion that may degrade the error vector magnitude and linearity performance. As such, there is a need for a power amplifier with a controllable driver stage that is configured to compensate for gain expansion of the output stage.

### SUMMARY

Disclosed is a power amplifier having an output stage having a radio frequency (RF) output and an RF input and a driver stage having a driver input coupled to the RF input, a control input, and a driver output, wherein the driver stage is configured to have a controllable soft compression characteristic that substantially neutralizes a gain expansion characteristic of the output stage. Also included is a controller having a control output coupled to the control input of the driver stage, wherein the controller is configured to generate a control signal at the control output that controls the soft compression characteristic of the driver stage.

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure and, together with the description, serve to explain the principles of the disclosure.

FIG. 1 is a diagram depicting a generalized embodiment of a power amplifier having a driver configured to adapt for a variable expansion characteristic of the output stage in accordance with the present disclosure.

FIG. 2 is a diagram depicting a detailed first embodiment of a controlled compression point driver using a variable size cascode device.

FIG. 3 is a graph depicting exemplary gain characteristics of a driver using two segments, one of which has a different cascode device size.

FIG. 4 is a diagram depicting an alternate embodiment of a driver with controlled compression characteristic using variable cascode bias voltage.

FIG. 5 is a graph depicting the gain curves for the driver using variable cascode voltage for at least one segment of the driver.

FIG. 6 shows another alternative embodiment of a driver with variable compression characteristic using variable bypass capacitance to control voltages at the cascode nodes.

FIG. 7 is a graph depicting gain curves for the driver using variable cascode bypass capacitance for at least one segment of the driver.

FIG. 8 is a diagram depicting a segmented driver with two or more segments configured to control of the compression characteristic of the segmented driver and having an offset bias voltage for at least one segment.

FIG. 9 is a diagram showing how the disclosed power amplifier may interact with user elements such as wireless communication devices.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

The present disclosure relates to a special type of driver stage that has a controlled soft-compression characteristic that may be adjusted/controlled in order to accurately compensate for the power amplifier output stage expansion. The key is to adjust the voltage drain-to-source (VDS) seen by the driver transconductance device, which in turn determines when the driver enters into soft compression, which compensates for the output stage expansion. Several embodiments according to the present disclosure can be applied to a single driver stage or a segmented driver where only one or several segments have the compression control. A first embodiment uses variable offset voltages for the cascode nodes. Another embodiment uses a variable bypass capacitance at the cascode nodes. Another embodiment uses different or tunable sizes for the cascode device. All embodiments have the same target of controlling the point when the transconductance device starts compressing. By adjusting the control on the driver compression, the overall power amplifier amplitude modulation-amplitude modulation characteristic can be modified to achieve a flat gain without any early expansion. This is instrumental for the advanced 5G power amplifiers with extremely demanding linearity constraints.

Most existing power amplifiers are using a relatively linear driver stage. The gain characteristic of the driver also is the native curve given by the devices under a growing signal level, which may include some rectification of the stage bias points. This may change the gain of the stage due to a signal-dependent bias point.

The output stage often has an expansion at mid-power, particularly when it is debiased to save power in quiescent point. As such, the overall characteristic has a remaining peaking/expansion of gain, which may degrade the overall linearity of the power amplifier. What is desired is that the power amplifier be structured to provide a controlled way of compensating for the gain expansion.

The present disclosure relates to embodiments to achieve an overall flat gain for a power amplifier. The expansion may vary as a function of operation conditions: temperature, process corner, supply voltage, and so on. Therefore, what is needed is a driver having an adjustable gain characteristic where the soft compression that is supposed to compensate the output stage gain expansion can be adjusted.

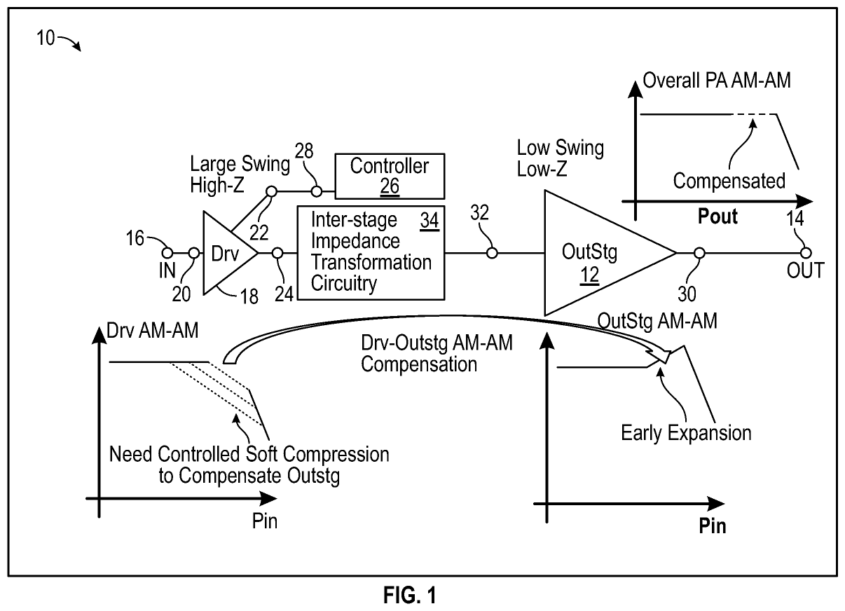

FIG. 1 is a diagram depicting a general embodiment of a power amplifier system 10 that is structured in accordance with the present disclosure to compensate for gain expansion in an output stage 12. The power amplifier system 10 has a radio frequency (RF) output 14 and an RF input 16, and a driver stage 18 with a driver input 20, a control input 22, and a driver output 24, wherein the driver stage 18 is configured to have a controllable soft compression characteristic that substantially neutralizes a gain expansion characteristic of the output stage 12. The driver input 20 is coupled to the RF input 16. The power amplifier system 10 also includes a controller 26 having a control output 28 coupled to the control input 22 of the driver stage 18. The output stage 12 has a power amplifier output 30 coupled to the RF output 14 and a power amplifier input 32 coupled to the driver output 24. In the exemplary embodiment of FIG. 1, an inter-stage impedance transformation circuitry 34 is coupled between the driver output 24 and the power amplifier input 32 of the output stage 12. The inter-stage impedance transformation circuitry 34 is configured to match output impedance of the driver stage 18 with the input impedance of the output stage 12.

FIG. 1 also shows a first graph of driver amplitude modulation-amplitude modulation (AM-AM) gain characteristic versus input power Pin. The first graph of the driver AM-AM gain characteristic illustrates a need for controlled soft compression to compensate for the expansion of gain in the output stage 18. Downwardly sloped short-dashed lines depicted in the graph of the driver AM-AM gain illustrate the controlled soft compression that the controller 26 is configured to provide based on input power Pin received at the driver input 16.

A second graph shown in FIG. 1 depicts an AM-AM gain characteristic versus the input power Pin for the output stage 12. This second graph illustrates gain expansion and points to early gain expansion. An arrow extending between the first graph and the second graph represents control of the gain expansion of the output stage 12 through controlled adjustment of soft compression of the driver stage 18.

A third graph shown in FIG. 1 depicts overall power amplifier AM-AM gain characteristic versus output power Pout. This third graph illustrates neutralization of the gain expansion of the output stage 12 provided through controlled adjustment of soft compression of the driver stage 18.

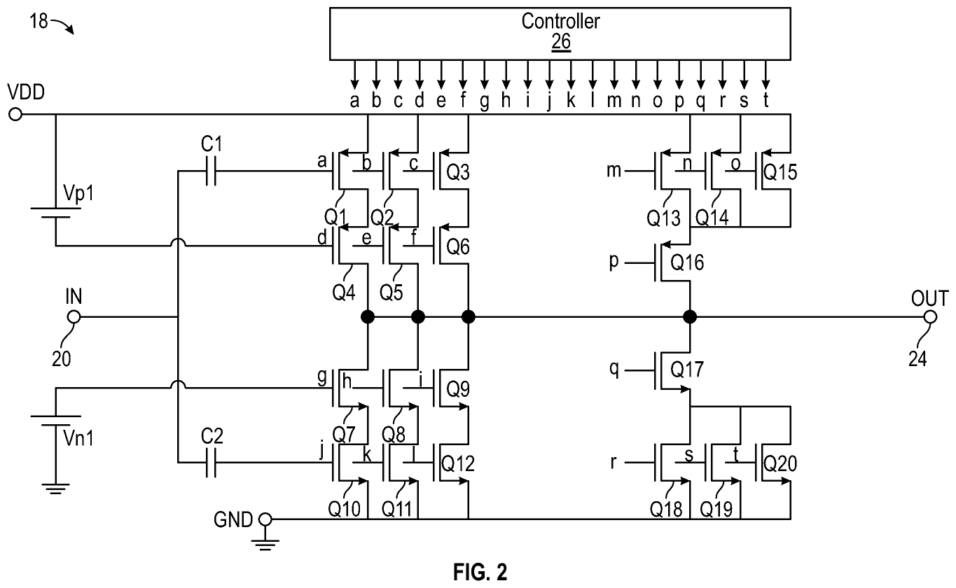

FIG. 2 shows a first embodiment of the driver stage 18 in which the controller 26 is configured to control soft compression of the driver stage 18 by adjusting the biasing of the transistors Q1 through Q20 that make up the driver stage 18. In this exemplary embodiment, the controller 26 generates bias signals at control outputs a through t, which are coupled to gates of the transistors Q1 through Q20, respectively. Note, that in some embodiments, the biasing of the transistors Q4, Q5, Q6, and Q16 may be achieved independent of the controller 26 by way of a bias source Vp1. In FIG. 2, the transistors Q1, Q2, Q3, Q4, Q5, Q6, Q13, Q14, Q15, and Q16 are positive type field-effect transistors (P-FETs). Note also, that in some embodiments, the biasing of the transistors Q7, Q8, Q9, Q10, Q11, Q12, Q17, Q18, Q19, and Q20 may be achieved independent of the controller 26 by way of another bias source Vn1. In FIG. 2, the transistors Q7, Q8, Q9, Q10, Q11, Q12, Q17, Q18, Q19, and Q20 are negative type field-effect transistors (N-FETs). A first capacitor C1 and a second capacitor C2 provide alternating current coupling between the driver input 20 and the transistor Q1 and the transistor Q10, respectively.

In the exemplary embodiment of FIG. 2, the controller 26 is configured to control the soft compression characteristic of the driver stage 18 by selecting which segments of the driver stage 18 are active. For example, a first segment made up of cascode drain-to-source couplings of transistors Q1, Q4, Q7, and Q10 is controlled by bias signals generated at the control outputs a, d, g, and j, respectively. A second segment made up of cascode drain-to-source couplings of transistors Q2, Q5, Q8, and Q11 is controlled by bias signals generated at the control outputs b, e, h, and k, respectively. A third segment made up of cascode drain-to-source couplings of transistors Q3, Q6, Q9, and Q12 is controlled by bias signals generated at the control outputs c, f, i, and l, respectively. A fourth segment made up of cascode drain-to-source couplings of transistors Q13, Q16, Q17, and Q18 is controlled by bias signals generated at the control outputs m, p, q, and r, respectively. The fourth segment also includes additional cascode transistors Q14 and Q15 that are coupled in parallel with the cascode transistor Q13. The additional cascode transistors Q14 and Q15 are biased by control signals generated at control outputs n and o, respectively. Additionally, the fourth segment further includes cascode transistors Q19 and Q20 that are biased by control signals generated at the control outputs s and t, respectively. Controlled biasing of the cascode transistors Q14 and Q15 may be considered as providing a controllable device size for the transistor Q13. Similarly, controlled biasing of the cascode transistors Q17 and Q18 may be considered as providing a controllable device size for the transistor Q18.

In operation, the controlled compression characteristic of the driver stage 18 may be adjusted by controlling the effective device sizes of the transistors Q13 and Q18 by selectively biasing the transistors Q14 and Q15 and Q19 and Q20, respectively, to operate between being substantially fully conductive (i.e., ON) or substantially fully non-conductive (i.e., OFF). For example, in a first bias-based control mode/method, for lower levels of gain versus input power Pin, the controller 26 may bias neither or only one of the transistors Q14 and Q15 ON and bias only one or neither of the transistors Q19 and Q20 ON, thereby effectively reducing the device sizes of transistors Q13 and Q18, respectively. In contrast, for higher levels of gain versus input power Pin, the controller 26 may bias both the transistors Q14 and Q15 ON and bias both the transistors Q19 and Q20 ON, thereby effectively increasing the device sizes of transistors Q13 and Q18, respectively.

In a second bias-based control mode/method, the controller 26 may selectively activate amplification by any one or combinations of the first, second, third, and fourth segments. For example, the controller 26 may select the first segment to provide amplification of an RF signal arriving at the driver input 20 by biasing transistors Q1 and Q10 ON by way of control signals generated at control outputs a and j, respectively. The controller 26 may select the second segment to provide amplification of the RF signal arriving at the driver input 20 by biasing transistors Q2 and Q11 ON by way of control signals generated at control outputs b and k, respectively. Similarly, the controller 26 may select the third segment to provide amplification of the RF signal arriving at the driver input 20 by biasing transistors Q3 and Q12 ON by way of control signals generated at control outputs c and l, respectively. Also, the controller 26 may select the fourth segment to provide amplification by biasing ON any of transistors Q13, Q14, and Q15 along with any of the transistors Q18, Q19, and Q20. This second biasing mode/method allows the controller 26 to control the soft compression characteristic of the driver stage 18 and thereby control the gain expansion characteristic of the output stage 12. As such, the controller 26 may flatten the gain expansion characteristic of the output stage 12 as a function of input power Pin, output power Pout, or other determinable variables that are associated with the gain expansion of the output stage 12.

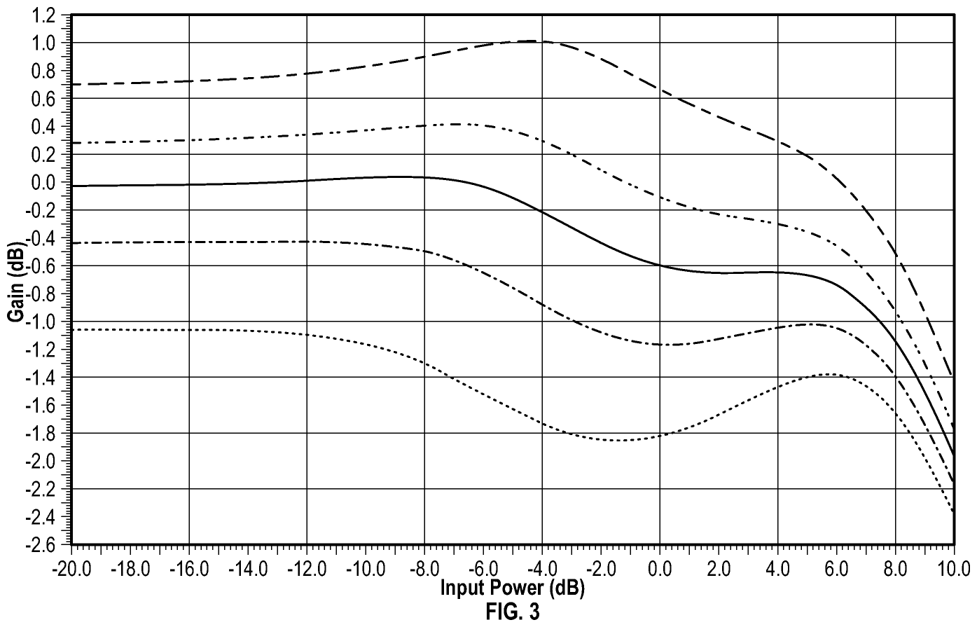

A third bias-based control mode/method combines the first and second bias-based control modes/methods to provide relatively finer-grained control of the soft compression characteristic of the driver stage 18 and thereby provide finer-grained control the gain expansion characteristic of the output stage 12. For example, FIG. 3 illustrates exemplary finer-grained control of the soft compression gain characteristics of the driver stage 18 having two segments active as amplifier segments, one of which being the fourth segment having the controllable cascode device size. Note that there are dips in gain versus input power Pin for input power levels between about −4 dB and +4 dB. These dips in gain of the driver stage 18 counter the gain expansion characteristic of the output stage 12 resulting in an over all more linear gain response for the amplifier system 10.

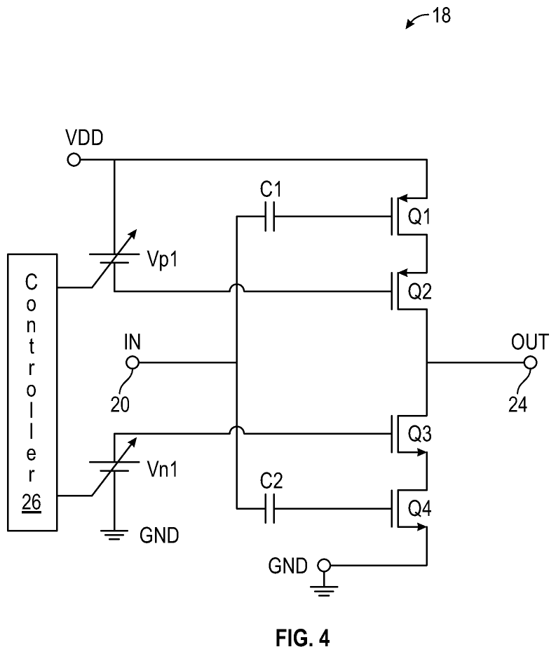

FIG. 4 is a diagram depicting another exemplary embodiment of the driver stage 18 having a controlled compression characteristic by way of the cascode bias voltage sources Vp1 and Vn1, which in this embodiment are controlled by the controller 26. In this case, the gain compression characteristic of the driver stage 18 is determined by a point at which the transconductance devices that are the transistors Q2 and Q3 are starting to enter in a triode region for part of the period of the RF signal arriving at the driver input 20. This point is set by the direct current (DC) bias voltage at each of the cascode nodes that are between Q1 and Q2 and Q3 and Q4. The DC bias voltage at the cascode nodes is controlled by the cascode bias voltage sources Vp1 and Vn1, which in turn sets the DC drain-to-source VDS voltages of the transistors Q2 and Q3. The instantaneous VDS voltages vary in time with variation of the RF signal. An equivalent gain for the driver stage 18 is determined by averaging the instantaneous gain for the different time instances of a cycle of the RF signal.

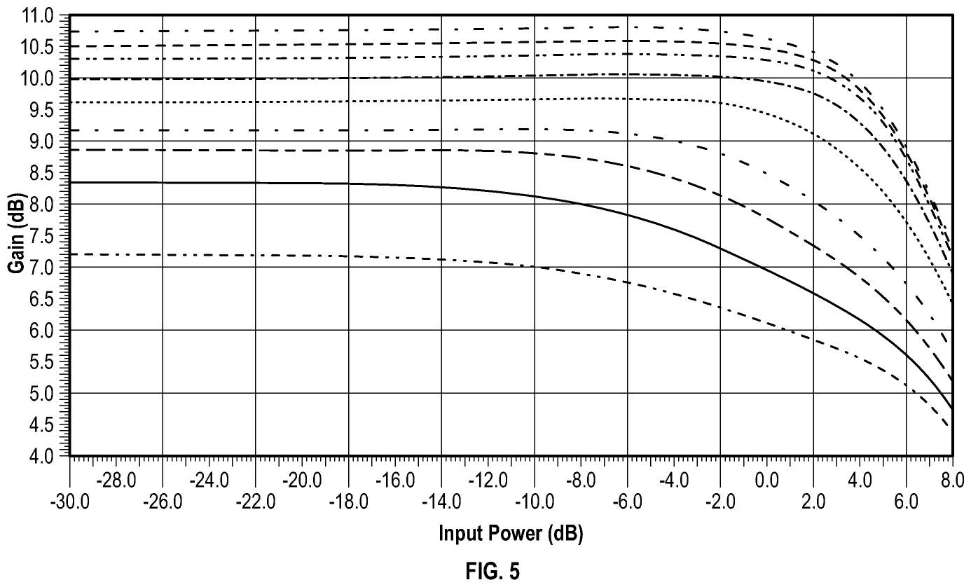

FIG. 5 is a graph depicting the gain curves for the exemplary embodiment of the driver stage 18 depicted in FIG. 4. Notice that a gain control from between 6 dB and 10.5 dB is providable by the controller 26 for an input power Pin of around 0.0 dB.

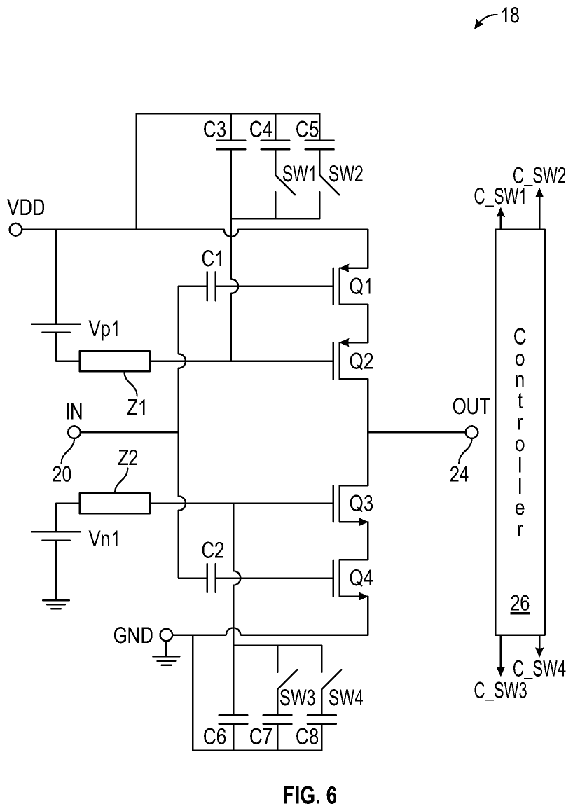

FIG. 6 shows another exemplary alternative embodiment of the driver stage 18 with variable compression characteristic using variable bypass capacitance to control voltages at the cascode nodes. In this embodiment, a first capacitor array made up of capacitors C3, C4, and C5 is arranged in parallel between a supply voltage VDD and the gate of the transistor Q2 that is a P-type transconductance device. The capacitors C4 and C5 are selectively coupled in parallel with the capacitor C3 by way of series switches SW1 and SW2, respectively. A second capacitor array made up of capacitors C6, C7, and C8 is arranged in parallel between a fixed voltage node GND and the gate of the transistor Q3 that is a N-type transconductance device. The capacitors C7 and C8 are selectively coupled in parallel with the capacitor C6 by way of series switches SW3 and SW4, respectively. The controller 26 is configured to selectively open and close the switches SW1, SW2, SW3, and SW4 by way of switch control signals C_SW1, C_SW2, C_SW3 and C_SW4, respectively, to adjust the soft compression characteristic of the driver stage 18 to flatten the gain expansion characteristic of the output stage 12. RF limiting impedances Z1 and Z2 are coupled between the gates of transistors Q2 and Q3 and the supply voltage VDD and the fixed voltage node GND, respectively. The controller 26 in control of the first capacitor array and the second capacitor array of the driver stage 18 may flatten the gain expansion characteristic of the output stage 12 as a function of input power Pin, output power Pout, or other determinable variables that are associated with the gain expansion of the output stage 12.

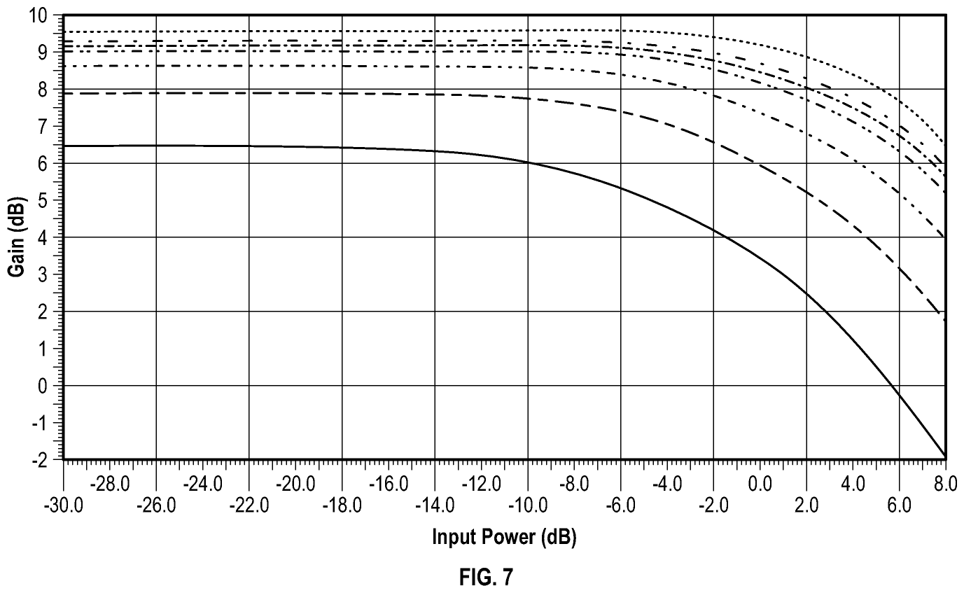

FIG. 7 illustrates gain curves for the driver stage 18 that uses variable cascode bypass capacitance provided by the first and second capacitor arrays for at least one segment of the driver stage 18. Notice that a gain control from between 4 dB and 9.5 dB is providable by the controller 26 for an input power Pin of around-2.0 dB.

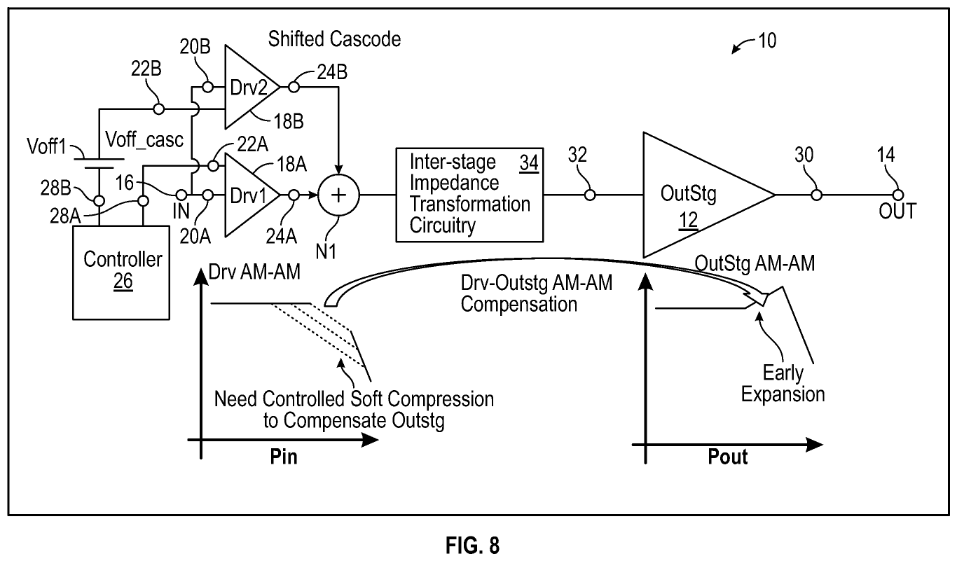

FIG. 8 is a diagram of the power amplifier system 10 depicting a first driver stage 18A having a first driver input 20A, a first bias control input 22A, a first driver output 24A, and a second driver stage 18B having a second driver input 20B, a second bias control input 22B, and a second driver output 24B. The first driver input 20A and the second driver input 20B are both coupled to the RF input 16. In this exemplary embodiment, the controller 26 generates a first bias control signal at a first bias control output 28A that is coupled to the first bias control input 22A. The first bias control signal controls biasing to at least one segment of the first driver stage 18A. The controller 26 also generates a second bias control signal that is combined with an offset bias voltage Voff_casc. The combined second bias signal and offset bias voltage Voff_casc is applied to at least one segment of the second driver stage 18B. In this exemplary embodiment, an offset bias source Voff_1 coupled between a second bias control output 28B and the second control input 22B generates the offset bias voltage Voff_casc. Amplified versions of an RF signal arriving at the RF input 16 are generated at the first driver output 24A and the second driver output 24B before being summed together at a summation node N1.

In operation, the controller 26 controls the soft compression characteristic of one or both of the first driver stage 18A and the second driver stage 18B and thereby controls the gain expansion characteristic of the output stage 12. As such, the controller 26 may flatten the gain expansion characteristic of the output stage 12 as a function of input power Pin, output power Pout, or other determinable variables that are associated with the gain expansion of the output stage 12.

The disclosed structures can be applied for both single-ended amplifiers and differential ones, for Doherty, quadrature power amplifiers, and so on. The disclosed structures and control methods may be realized in N-FET or P-FET or complementary configurations. They can also be realized using metal oxide semiconductor field-effect transistors, junction field-effect transistors, pseudomorphic high electron mobility transistors, and even bipolar junction transistors or heterojunction bipolar transistor amplifiers.

The controlled driver compression characteristic can be used to accurately compensate for the output stage expansion, which may vary as a function of operation conditions. A variable control of the compression can be applied to track the variable expansion. A blind or a sense and force mechanism can be used for controlling the compression of the driver. An open-loop or a closed-loop control of the driver compression can be used.

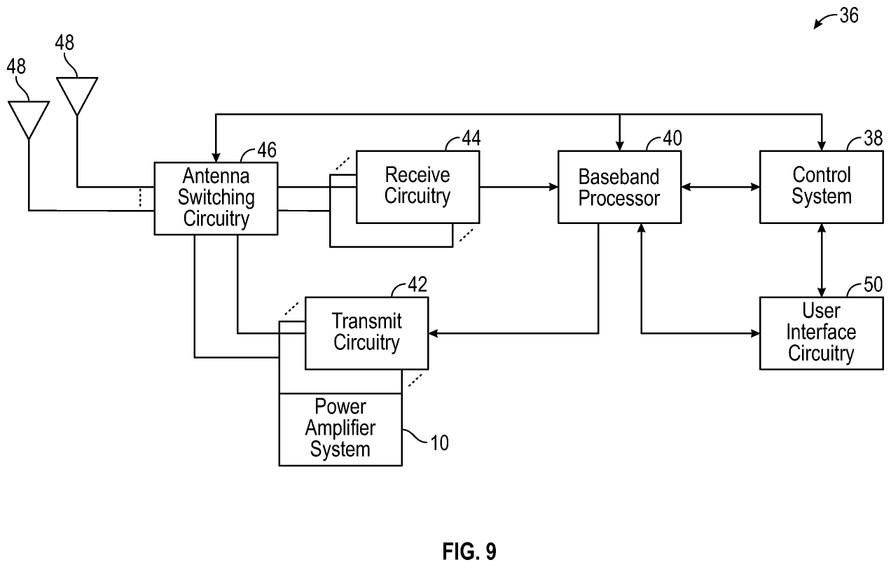

With reference to FIG. 9, the concepts described above may be implemented in various types of wireless communication devices or user elements 36, such as mobile terminals, smart watches, tablets, computers, navigation devices, access points, and the like that support wireless communications, such as cellular, wireless local area network (WLAN), Bluetooth, and near-field communications. The user elements 36 will generally include a control system 38, a baseband processor 40, transmit circuitry 42 that includes a power amplifier system 10, receive circuitry 44, antenna switching circuitry 46, multiple antennas 48, and user interface circuitry 50. The receive circuitry 44 receives radio frequency signals via the antennas 48 and through the antenna switching circuitry 46 from one or more basestations. A low-noise amplifier and a filter (not shown) cooperate to amplify and remove broadband interference from the received signal for processing. Downconversion and digitization circuitry (not shown) will then downconvert the filtered, received signal to an intermediate or baseband frequency signal, which is then digitized into one or more digital streams.

The baseband processor 40 processes the digitized received signal to extract the information or data bits conveyed in the received signal. This processing typically comprises demodulation, decoding, and error correction operations. The baseband processor 40 is generally implemented in one or more digital signal processors (DSPs) and application-specific integrated circuits (ASICs).

For transmission, the baseband processor 40 receives digitized data, which may represent voice, data, or control information, from the control system 38, which it encodes for transmission. The encoded data are output to the transmit circuitry 42, where they are used by a modulator (not shown) to modulate a carrier signal that is at a desired transmit frequency or frequencies. A power amplifier (not shown) will amplify the modulated carrier signal to a level appropriate for transmission and deliver the modulated carrier signal to the antennas 48 through the antenna switching circuitry 46. The antennas 48 and the replicated transmit and receive circuitries 42, 44 may provide spatial diversity. Modulation and processing details will be understood by those skilled in the art.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

1. A power amplifier system comprising:
an output stage having a radio frequency output and power amplifier input;
a driver stage having a driver input coupled to the RF input, a control input, and a driver output coupled to the power amplifier input, wherein the driver stage is configured to have a controllable by-pass capacitance in response to control signals; and
a controller having control outputs coupled to the control input of the driver stage, wherein the controller is configured to generate the control signals that adjusts the by-pass capacitance associated with selectable by-pass capacitors coupled to gates of transistors comprising the driver stage to substantially neutralize a gain expansion characteristic of the output stage.

2. The power amplifier system of claim 1 wherein the driver stage has segments comprised of cascode drain-to-source coupled transistors that are configured to be biased ON and biased OFF by the control signals generated at the control outputs of the driver stage.

3. The power amplifier system of claim 2 wherein the driver stage is configured, in response to the control signal bias OFF of at least one of the cascode drain-to-source coupled transistors of at least one of the segments, to adjust a soft compression characteristic of the driver stage to substantially neutralize the gain expansion characteristic of the output stage.

4. The power amplifier system of claim 2 further comprising at least one additional transistor coupled in parallel with at least one of the cascode drain-to-source coupled transistors, wherein the at least one additional transistor is configured to be biased ON and OFF in response to the control signal to effectively change the size of the at least one of the cascode drain-to-source coupled transistors.

5. The power amplifier system of claim 4 wherein the driver stage is configured, in response to the control signal bias OFF of the at least one additional transistor coupled in parallel with the at least one of the cascode drain-to-source coupled transistors of at least one of the segments, to adjust the soft compression characteristic of the driver stage to substantially neutralize the gain expansion characteristic of the output stage.

6. The power amplifier system of claim 2 further including a voltage offset source coupled between the controller and at least one segment.

7. (canceled)

8. The power amplifier system of claim 1 wherein the drive stage responds to the control signal by decreasing the by-pass capacitance associated with the driver stage and thereby adjusts the soft compression characteristic of the driver stage to substantially neutralize a gain expansion characteristic of the output stage.

9. The power amplifier system of claim 1 wherein the by-pass capacitors are arranged in a capacitor array that is configured to selectively couple selected ones of the by-pass capacitors between the gates of transistors comprising the driver stage and a fixed voltage node.

10. A method of operating a power amplifier system comprising an output stage, a driver stage configured to have a controllable soft compression characteristic, and a controller configured to generate and send a soft compression control signal to the driver stage, the method comprising:
determining by way of the controller that the output stage is entering early gain expansion;
generating the soft compression control signal upon determination of early gain expansion in the output stage; and
sending the soft compression control signal to select by-pass capacitance of selectable by-pass capacitors associated with the driver stage to adjust the soft compression characteristic of the driver stage and thereby substantially reduce the gain expansion of the output stage.

11. The method of operating the power amplifier system of claim 10 wherein the soft compression control signal causes the driver stage to de-activate one or more segments of the driver stage in response to the soft compression control signal.

12. The method of operating the power amplifier system of claim 10 wherein the soft compression control signal causes the driver stage to reduce an effective size of one or more transistors of a segment of the driver stage.

13. The method of operating the power amplifier system of claim 10 wherein the soft compression control signal causes the driver stage to de-activate one or more segments of the driver stage in response to the soft compression control signal and causes the driver stage to reduce an effective size of one or more transistors of a segment of the driver stage.

14. The method of operating the power amplifier system of claim 10 wherein the soft compression control signal causes a decrease in the by-pass capacitance associated with the driver stage and thereby adjusts the soft compression characteristic of the driver stage to substantially neutralize a gain expansion characteristic of the output stage.

15. A wireless communication device comprising:
a baseband processor;
transmit circuitry configured to receive encoded data from the baseband processor and to modulate a carrier signal with the encoded data, wherein the transmit circuitry comprises:
an output stage having a radio frequency (RF) output and power amplifier input;
a driver stage having a driver input coupled to the RF input, a control input, and a driver output coupled to the power amplifier input, wherein the driver stage is configured to have a controllable by-pass capacitance in response to control signals; and
a controller having control outputs coupled to the control input of the driver stage, wherein the controller is configured to generate the control signals that adjust the by-pass capacitance associated with selectable by-pass capacitors coupled to gates of transistors comprising the driver stage to substantially neutralize a gain expansion characteristic of the output stage.

16. The wireless communication device of claim 15 wherein the driver stage has segments comprised of cascode drain-to-source coupled transistors that are configured to be biased ON and biased OFF by the control signals generated at the control outputs of the driver stage.

17. The wireless communication device of claim 16 wherein the driver stage is configured to bias OFF at least one of the cascode drain-to-source coupled transistors of at least one of the segments to adjust the soft compression characteristic of the driver stage to substantially neutralize a gain expansion characteristic of the output stage.

18. The wireless communication device of claim 16 further including a voltage offset source coupled between the controller and at least one segment.

19. (canceled)

20. The wireless communication device of claim 15 wherein the driver stage responds to the control signal by decreasing the by-pass capacitance associated with the driver stage and thereby adjusts the soft compression characteristic of the driver stage to substantially neutralize a gain expansion characteristic of the output stage.
